(19) United States
(12) Patent Application Publication
(10) Pub. No.: US 2026/0237414 A1
(43) Pub. Date: Aug. 13, 2026

(54) SEMICONDUCTOR SYSTEM AND OPERATING METHOD THEREOF

(71) Applicants: TAIWAN SEMICONDUCTOR MANUFACTURING COMPANY, LTD, Hsinchu (TW); NATIONAL TSING HUA UNIVERSITY, Hsinchu City (TW)

(72) Inventors: Win-San KHWA, Taipei City (TW); Chiao-Yen CHENG, Hsinchu City (TW); Ping-Chun WU, Taichung City (TW); Ashwin Sanjay LELE, San Jose, CA (US); Bo ZHANG, San Jose, CA (US); Ping-Sheng WU, Hsinchu City (TW); Meng-Fan CHANG, Taichung City (TW)

(73) Assignees: TAIWAN SEMICONDUCTOR MANUFACTURING COMPANY, LTD, Hsinchu (TW); NATIONAL TSING HUA UNIVERSITY, Hsinchu City (TW)

(21) Appl. No.: 19/191,826

(22) Filed: Apr. 28, 2025

Related U.S. Application Data
(60) Provisional application No. 63/749,299, filed on Jan. 24, 2025.

(51) Int. Cl. G11C 7/10

(52) U.S. Cl. CPC G11C 7/1084; G11C 7/1006; G11C 7/1096

(57) ABSTRACT

A semiconductor system comprises a write circuit, the write circuit configured to receive an input data having a first accumulation size; a first buffer circuit, the buffer circuit has a second accumulation size, and is configured to store the input data when the first accumulation size is smaller than the second accumulation size; a memory array, the memory array is configured to store the input data and transmit the input data to the buffer circuit when the first accumulation size is larger than the second accumulation size of the input data.

### CROSS REFERENCE TO RELATED APPLICATIONS

This application claims the benefit of U.S. Provisional Application No. 63/749,299, filed on Jan. 24, 2025, the entirety of which is incorporated by reference herein.

### BACKGROUND

A semiconductor system processes a Compute in Memory (CIM) operation of an input data to generate an output data after arithmetic processes. The input data is transferred from a local memory to a CIM macro of the semiconductor device. The CIM macro performs a computation process, such as a convolutional neural network (CNN) operation to generate the output data.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a semiconductor system, illustrated in accordance with some embodiments of the present disclosure.

FIG. 2A is a schematic diagram of a weight filter, illustrated in accordance with some embodiments of the present disclosure.

FIG. 2B is a schematic diagram of an input feature map, illustrated in accordance with some embodiments of the present disclosure.

FIG. 3 is a schematic diagram of a CNN process with block-based flow, corresponding to the weight filter and the input feature map in FIGS. 2A and 2B, illustrated in accordance with some embodiments of the present disclosure.

FIG. 4 is a flowchart diagram of a computation process operated by the semiconductor system, illustrated in accordance with some embodiments of the present disclosure.

FIG. 5 is a schematic diagram of a logic circuit included in the write circuit shown in FIG. 1, illustrated in accordance with some embodiments of the present disclosure.

FIG. 6A is a schematic diagram of further details of the selector shown in FIG. 5, illustrated in accordance with some embodiments of the present disclosure.

FIG. 6B is a circuit diagram of part of the processing circuit as shown in FIG. 1, illustrated in accordance with some embodiments of the present disclosure.

FIG. 7 is a schematic diagram of a system for designing and manufacturing at least one of the semiconductor systems described herein, illustrated in accordance with some embodiments of the present disclosure.

FIG. 8 is a block diagram of an integrated circuit (IC)/semiconductor system manufacturing system, and an IC manufacturing flow associated therewith, illustrated in accordance with some embodiments of the present disclosure.

FIG. 9 is a flow diagram of a method of operating the semiconductor system illustrated in accordance with some embodiments of the present disclosure.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

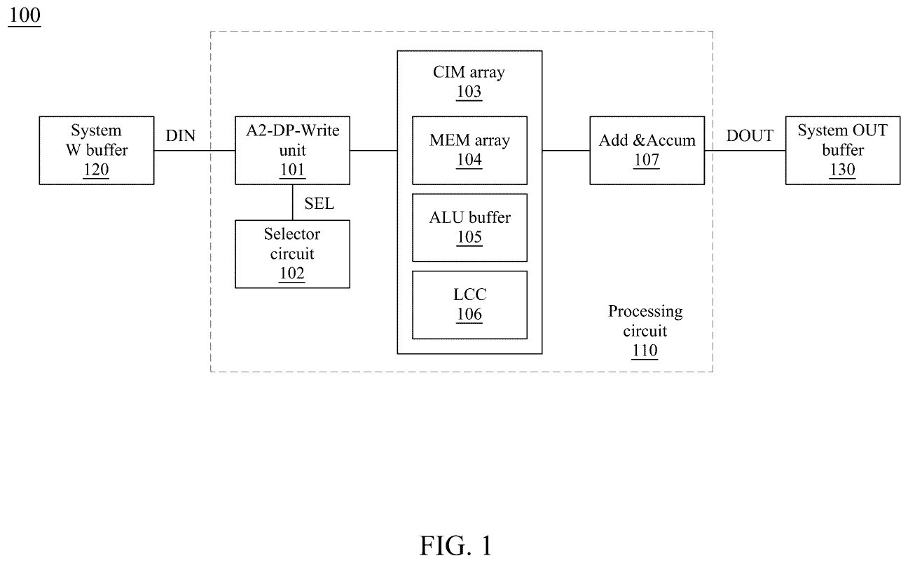

FIG. 1 is a schematic diagram of a semiconductor system 100, illustrated in accordance with some embodiments of the present disclosure. As illustratively shown in FIG. 1, the semiconductor system 100 includes a processing circuit 110, buffer circuits 120 and 130. In some embodiments, the buffer circuit 120 is configured to generate input data DIN. The processing circuit 110 is configured to receive the input data DIN, and generate an output data DOUT according to the input data DIN. The buffer circuit 130 is configured to receive DOUT.

As illustratively shown in FIG. 1, the processing circuit 110 includes a write circuit 101, a selector circuit 102, a memory circuit 103, and a computing circuit 107. The memory circuit 103 includes a memory array 104 (MEM array 104), a buffer circuit 105, and a computing circuit 106. In some embodiments, the write circuit 101 is configured to receive the input data DIN from the buffer circuit 120, and transmit the input data DIN to the memory circuit 103.

Specifically, the write circuit 101 is configured to transmit the input data DIN according to a select signal SEL. The selector circuit 102 is configured to generate the select signal SEL according to the input data DIN and the buffer circuit 105. In some embodiments, the input data DIN has an accumulation size N_{CH}, and the buffer circuit 105 has an accumulation size N_{CIM}. When the accumulation size N_{CH} is larger than the accumulation size N_{CIM}, the write circuit 101 transmits the input data DIN to the memory array 104, and the memory array 104 is configured to store the input data DIN. When the accumulation size N_{CH} is smaller than the accumulation size N_{CIM}, the write circuit 101 transmits the input data DIN to the buffer circuit 105, and the buffer circuit is configured to store the input data DIN.

In some embodiments, the quantity of bits stored in the buffer circuit 105 is the same as the accumulation size N_{CIM}. The quantity of bits stored in the memory array 104 is the same as the accumulation size N_{CH}.

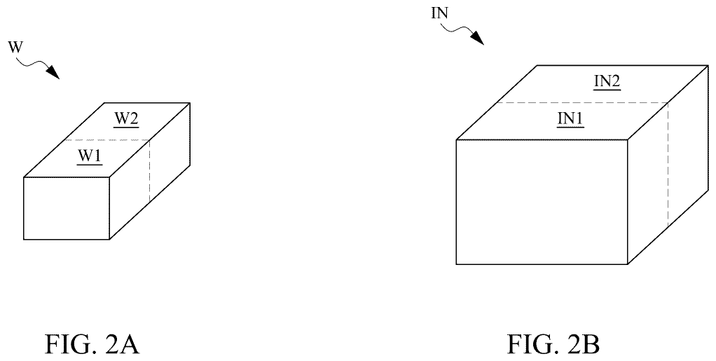

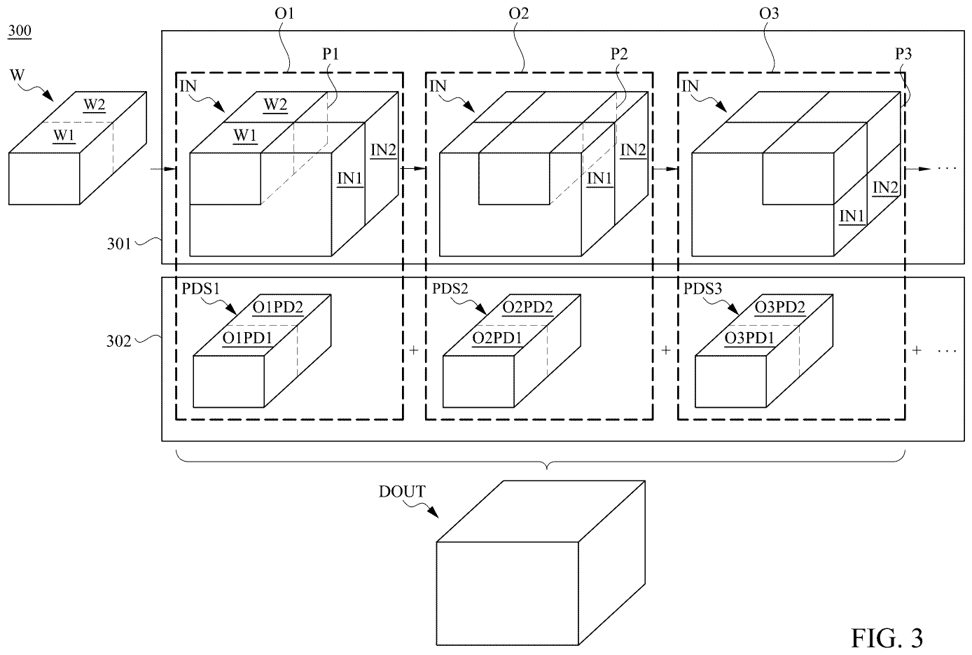

Then, the buffet circuit 105 transmits the input data DIN to the computing circuits 106 and 107. The computing circuits 106 and 107 are configured to perform a computation process to the input data DIN and generate the output data DOUT by the computing circuit 107. Further details regarding the operation of the computation process, the accumulation sizes N_{CH}, and N_{CIM} are discussed in FIG. 2A to FIG. 3 and corresponding paragraph of the present disclosure.

In some approaches, the arithmetic buffer circuit of a semiconductor system receives an input data from a write circuit and stores a limited size of the input data. When a size of the input data is smaller than the limited size of the arithmetic buffer circuit can store, the input data firstly transmitted through the memory array and then to the arithmetic buffer circuit. As a result, the semiconductor system suffers from low energy efficiency.

In some other approaches, when a size of the input data is larger than the limited size of the arithmetic buffer circuit can store, the write circuit transfers the limited size of the input data to the arithmetic buffer circuit multiple times to perform the computation process to the input data. Transferring the input data from the local buffer circuit to the write circuit causes energy waste and low energy efficiency.

Compared to above approaches, in some embodiments of present disclosure, the write circuit 101 transmits the input data DIN to the memory array 104 and the buffer circuit 105 according to the select signal SEL. When the accumulation size N_{CH} is smaller than the accumulation size N_{CIM}, the write circuit 101 transmits the input data DIN to the buffer circuit 105. When the accumulation size N_{CH} is larger than the accumulation size N_{CIM}, the write circuit 101 transmits the input data DIN to the memory array 104. Accordingly, the write circuit 101 transmits the input data DIN to the memory array 104 or the buffer circuit 105 based on the accumulation size N_{CH} of the input data DIN. As a result, when the write circuit 101 is applied to a semiconductor system, the energy waste is reduced and the energy efficiency is promoted.

In some embodiments, the semiconductor system 100 is configured to perform a computation process. The computation process is referred to as a Compute in Memory (CIM) process. The CIM process includes machine learning operation, for example, a convolutional neural network (CNN) operation.

In some embodiments, the semiconductor device 100 includes but not limited to Central Processing Unit (CPU), Micro Processing Unit (MPU), Micro Control Unit (MCU), or other similar processing unit in practical application. In some embodiments, the buffer circuits 120 and 130 are implemented by a local memory system, such as static random-access memory (SRAM). In the present disclosure, the buffer circuit 120 is implemented by a system weight (W) buffer, and the buffer circuit 130 is implemented by a system output buffer. The buffer circuit 105 is implemented by an arithmetic logic unit (ALU). The buffer circuit 105 is implemented by an buffer, and is configured to store the input data bits of the input data DIN. The computing circuit 106 is implemented by a local compute cell (LCC), and is configured to perform the CNN operation to the input data DIN. The computing circuit 107 is implemented by an adder tree and an accumulator, and is configured to perform the CNN operation to the input data DIN. The CNN operation includes an inner product operation and the summation operation, but the present disclosure is not limited to these operations.

In some embodiments, the write circuit 101 is implemented by an accumulation-size-aware data path (A2-DP) write unit. In some embodiments, the memory circuit 103 is implemented by a Compute-In-Memory (CIM) array. In some embodiments, the computing circuit 107 is implemented by an adder tree and an accumulator (Add & Accum).

FIG. 2A is a schematic diagram of a weight filter W, illustrated in accordance with some embodiments of the present disclosure. As illustratively shown in FIG. 2A, the weight filter W includes weight bits W1 and W2. In some embodiments, each of the weight bits W1 and W2 includes one bit of weight parameter.

Referring to FIG. 2A and FIG. 1, the quantity of bits of the weight filter W corresponds to the accumulation size N_{CIM} of the buffer circuit 105. In some embodiments, the quantity of bits of the weight filter W is determined according to the capacity of the buffer circuit 105. Specifically, the capacity of the buffer circuit 105 is a quantity of bits stored in the buffer circuit 105. In some embodiments, when the capacity of the buffer circuit 105 is increased, the accumulation size N_{CIM} is increased.

In some embodiments, the quantity of bits of the weight filter W is determined according to a quantity of bits in the computing circuit 106 processes in one convolution operation. The quantity of bits in the computing circuit 106 processes in one convolution operation is the accumulation size N_{CIM}. When the quantity of bits in the computing circuit 106 can process is increased, the accumulation size N_{CIM} is increased. In some embodiments, the quantity of bits in the computing circuit 106 is equal to the quantity of bits stored in the buffer circuit 105, such that an inner product operation is performed to the bits in the computing circuits 106. Accordingly, in some embodiments, the accumulation size N_{CIM} is equal to the quantity of bits stored in the buffer circuit 105. Further details regarding the operation of the weight filter W are discussed in FIG. 3 and the corresponding paragraph of the present disclosure.

FIG. 2B is a schematic diagram of an input feature map IN, illustrated in accordance with some embodiments of the present disclosure. As illustratively shown in FIG. 2B, the input feature map IN includes feature maps IN1 and IN2. In some embodiments, each of the feature maps IN1 and IN2 includes a plurality of bits of the input data DIN.

Referring to FIG. 2B and FIG. 1, the input feature map IN corresponds to the input data DIN. The quantity of bits of the input feature map IN corresponds to the accumulation size N_{CH} of the input data DIN. In some embodiments, the accumulation size N_{CH} is the quantity of bits of the input data DIN. When the quantity of bits of the input data DIN is increased, the accumulation size N_{CH} is increased. The feature maps IN1 and IN2 are the bits of the input data DIN transmitted to the processing circuit 110 from the buffer circuit 120. Further details regarding the operation of the input feature map IN is discussed in FIG. 3 and the corresponding paragraph of the present disclosure.

In some embodiments, in the CNN operation, the weight filter W refers to as weight matrix having the accumulation size N_{CIM} of bits. The input feature map IN refers to as input data having the accumulation size N_{CH} of bits. During the CNN operation, the weight filter W is applied to each bits of the input feature map IN in one or more convolution operations, such as inner product computation. After the weight filter W is applied to each bits of the input feature map IN, an output feature map is generated as a product sum. When the quantity of bits of the weight filter W is larger than the quantity of bits of the input feature map IN, one convolution operation is performed. When the quantity of bits of the weight filter W is lower than the quantity of bits of the input feature map IN, multiple convolution operations are performed.

In some embodiments, the quantity of bits of the weight filter W is larger than the quantity of bits of the input feature map IN. In some other embodiments, the quantity of bits of the weight filter W is smaller than the quantity of bits of the input feature map IN. In the embodiments of the present disclosure, the schematic diagrams shown in FIG. 2A and FIG. 2B are for illustrative purpose. In various embodiments, the weight filter W is implemented by various kinds of weight filters and the input feature map IN is implemented by various kinds of feature maps.

FIG. 3 is a schematic diagram of a CNN process 300 with block-based flow, corresponding to the weight filter W and the input feature map IN as shown in FIG. 2A and FIG. 2B, illustrated in accordance with some embodiments of the present disclosure. As illustratively shown in FIG. 3, the CNN process 300 includes a product operation 301 and a summation operation 302. The product operation 301 includes convolution operations O1-O3.

In the product operation 301, the weight filter W is applied to the input feature map IN and generates intermediate outputs in the convolution operations O1-O3. In some embodiments of the present disclosure, the intermediate outputs are product sums PDS1, PDS2, and PDS3.

During the convolution operations O1, the weight filter W is applied to a first part P1 of the input feature map IN, and the first part P1 of the input feature map IN has the same quantity of bits as the weight filter W. Specifically, in the convolution operation O1, a product O1PD1 is generated by calculating the inner product of the weight W1 and a first bit of the first part P1 of the feature map IN1. A product O1PD2 is generated by calculating the inner product of the weight W2 and a second bit of the first part P1 of the feature map IN2. The product sum PDS1 is generated by adding the products O1PD1 and O1PD2. After completing the convolution operations O1, the product operation 301 continues to the convolution operations O2.

During the convolution operations O2, the weight filter W is applied to a second part P2 of the input feature map IN, and the second part P2 of the input feature map IN has the same quantity of bits as the weight filter W. It is to be noticed that the second part P2 of the input feature map IN is determined by shifting one bit of the first part P1 on the input feature map IN.

Specifically, in the convolution operation O2, a product O2PD1 is generated by calculating the inner product of the weight W1 and a first bit of the second part P2 of the feature map IN1. A product O2PD2 is generated by calculating the inner product of the weight W2 and a second bit of the second part P2 of the feature map IN2. The product sum PDS2 is generated by adding the products O2PD1 and O2PD2. After completing the convolution operations O2, the product operation 301 continues to the convolution operations O3.

During the convolution operations O3, the weight filter W is applied to a third part P3 of the input feature map IN, and the third part P3 of the input feature map IN has the same quantity of bits as the weight filter W. Similarly, the third part P3 of the input feature map IN is determined by shifting one bit of the second part P2 on the input feature map IN. The third part P3 of the input feature map IN is shifted from the first part P1 of the input feature map IN by two bits on the input feature map IN.

Specifically, in the convolution operation O3, a product O3PD1 is generated by calculating the inner product of the weight W1 and a first bit of the third part P3 of the feature map IN1. A product O3PD2 is generated by calculating the inner product of the weight W2 and a second bit of the third part P3 of the feature map IN2. The product sum PDS3 is generated by adding the products O3PD1 and O3PD2. After completing the convolution operations O3, the product operation 301 continues the convolution operations similar to the convolution operations O1-O3. The convolution operations are performed until the weight filter W is applied to each bits of the input feature map IN. In some embodiments, the product sums other than the product sums PDS1-PDS3 are being generated when more convolution operations are performed.

In the summation operation 302, the product sums PDS1-PDS3 are added and accumulated to generate the output data DOUT. In some embodiments, the output data DOUT includes more product sums other than the product sums PDS1-PDS3 when more convolution operations are performed.

Referring to FIG. 3, FIG. 2A, FIG. 2B, and FIG. 1, during the CNN process 300, when the accumulation size N_{CH} is larger than the accumulation size N_{CIM}, the computing circuit 106 is configured to process different parts of the DIN in order, to generate different parts of the DOUT, corresponding to the product sums PDS1-PDS3, in order. Specifically, the memory array 104 transmits the first part P1 of the input data DIN to the buffer circuit 105. Then, the buffer circuit 105 transmits the first part P1 of the input data DIN to the computing circuit 106, such that the computing circuit 106 processes the first part P1 of the input data DIN with the weight filter W. Accordingly, the computing circuit 106 generates the first part P1 of DOUT, such as PDS1 shown in FIG. 3. After the computing circuit 106 generates the first part P1 of DOUT, the memory array 104 transmits the second part P2 of the input data DIN to the buffer circuit 105. Then, the computing circuit 106 further processes the second part P2 of the input data DIN with the weight filter W and generates the second part P2 of DOUT, such as PDS2 shown in FIG. 3. The processes corresponding to the third part P3 and further parts of the input data DIN are similar to the processes of the first part P1 and the second part P2, and thus some descriptions are not repeated herein for brevity.

In some embodiments, a quantity of bits in the first part P1 of the input data DIN is equal to a quantity of bits in the second part P2 of the input data DIN, and is equal to a quantity of bits in the third part P3 of the input data DIN. Each of the quantities of the first part P1, the second part P2, and the third part P3 is equal to the accumulation size N_{CH}.

Referring to FIG. 3 and FIG. 1, the processing circuit 110 is configured to perform the CNN process 300. The product operation 301 is implemented by the computing circuits 106. The summation operation 302 is implemented by the computing circuits 107. In some embodiments, the CNN process 300 includes the product operation 301 and the summation operation 302 of the weight filter W and the input feature map IN. The computing circuit 107 generates the output data DOUT after the CNN process 300 is performed.

In some embodiments, the CNN process 300 corresponds to the condition that the accumulation size N_{CH} is larger than the accumulation size N_{CIM}. In some other embodiments, when the accumulation size N_{CH} is smaller than the accumulation size N_{CIM}, the quantity of bits of the input feature map IN is smaller than the quantity of bits of the weight filter W. The weight filter W is applied to each of the bits of the input feature map IN in one convolution operation. As a result, only one convolution operation is performed in the product operation 301.

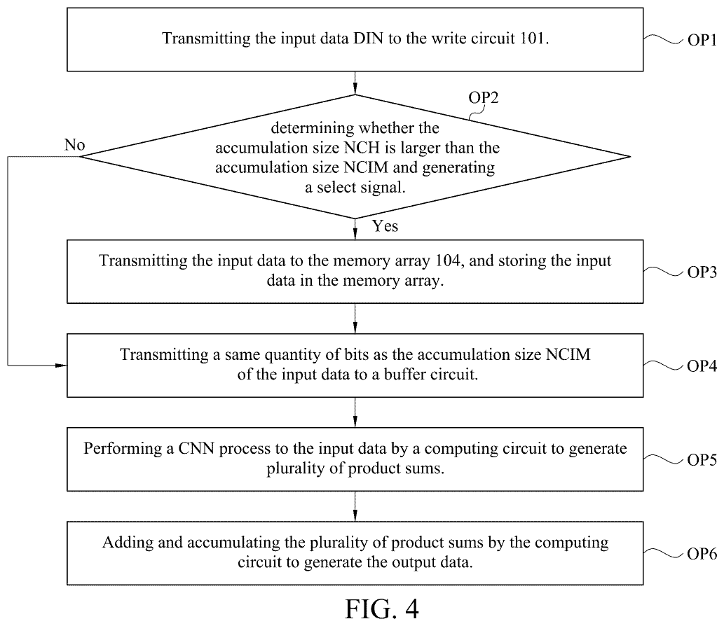

FIG. 4 is a flowchart diagram of the computation process 400 operated by the semiconductor system 100, illustrated in accordance with some embodiments of the present disclosure. As illustratively shown in FIG. 4, the computation process 400 includes operations OP1-OP6 for processing the input data DIN to generate the output data DOUT. In some embodiments, the operations OP5 and OP6 correspond to the CNN process 300 illustrated in FIG. 3.

During the operation OP1, the buffer circuit 120 transmits the input data DIN to the write circuit 101. In some embodiments, the input data DIN includes a plurality of bits, and the quantity of the bits is the same as the accumulation size N_{CH}. The semiconductor system 100 performs the operation OP2 after the operation OP1 is performed.

At the operation OP2, the selector circuit 102 determines whether the accumulation size N_{CH} is larger than the accumulation size N_{CIM} of the buffer circuit 106, and generates the select signal SEL. The write circuit 101 receives the select signal SEL.

Specifically, when the accumulation size N_{CH} is larger than the accumulation size N_{CIM}, the select signal SEL has a logic value “1”, and the semiconductor system 100 performs the operation OP3 after the operation OP2 is performed. On the other hand, when the accumulation size N_{CH} is smaller than the accumulation size N_{CIM}, the select signal SEL has a logic value “0”, and the semiconductor system 100 performs the operation OP4 after the operation OP2 is performed.

At the operation OP3, in response to the select signal SEL having the logic value “1”, the write circuit 101 transmits the input data DIN to the memory array 104, and the input data DIN is stored in the memory array 104. The semiconductor system 100 performs the operation OP4 after the operation OP3 is performed.

At the operation OP4, in response to the select signal SEL having the logic value “1”, the memory array 104 transmits a same quantity of bits as the accumulation size N_{CIM} of the input data DIN to the buffer circuit 105. On the other hand, in response to the select signal SEL having the logic value “0”, the write circuit 101 transmits each of the bits of the input data DIN to the buffer circuit 105. The semiconductor system 100 performs the operation OP5 after the operation OP4 is performed.

Referring to FIG. 4, FIG. 3, and FIG. 1, at the operation OP4, the input data DIN received by the buffer circuit 105 is implemented by the input feature map IN. Alternatively stated, the write circuit 101 transmits the input feature map IN to the buffer circuit 105 when the select signal SEL has the logic value “0”.

At the operation OP5, the computing circuit 106 performs a CNN process to the input data DIN. For example, the computing circuit 106 performs the CNN process 300 to the input data DIN with the weight filter W, to generate a plurality of product sums.

Specifically, the weight filter W from the computing circuit 106 is applied to the input data DIN, and generates a plurality of product sums such as the product sums PDS1-PDS3 as shown in FIG. 3. The product operation 301 as shown in FIG. 3 is an embodiment of the operation OP5, and thus some descriptions are not repeated herein for simplicity. The semiconductor system 100 performs the operation OP6 after the operation OP5 is performed.

At operation OP6, the plurality of product sums generated in operation OP5 are added and accumulated by the computing circuit 107 to generate the output data DOUT. For example, the computing circuit 107 adds and accumulates up the product sums PDS1-PDS3 generated in the product operation 301 in FIG. 3 to generate the output data DOUT. The computing circuit 107 further transmits the output data DOUT to the buffer circuit 130. The summation operation 302 as shown in FIG. 3 is an embodiment of the operation OP6, and is not repeated herein for simplicity. The computation process 400 is completed after the operation OP6 is performed.

In some embodiments, the computation process 400 is referred to as a Compute in Memory (CIM) process. The CIM process includes but not limited to machine learning operation, for example, a convolutional neural network (CNN) operation.

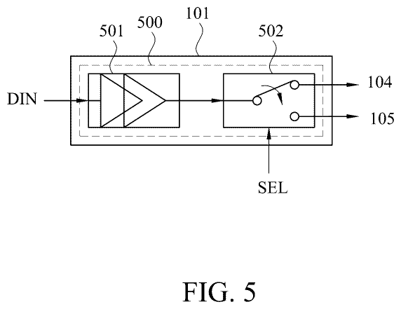

FIG. 5 is a schematic diagram of a logic circuit 500 included in the write circuit 101 shown in FIG. 1, illustrated in accordance with some embodiments of the present disclosure. As illustratively shown in FIG. 5, the logic circuit 500 includes a write driver 501 and a selector 502.

Referring to FIG. 5 and FIG. 1, the write driver 501 is configured to receive the input data DIN and transmit the input data DIN to the selector 502. The selector 502 is configured to receive the select signal SEL, and transmit the input data DIN to one of the memory array 104 and the buffer circuit 105 according to the select signal SEL.

In some embodiments, when the accumulation size N_{CH} is larger than the accumulation size N_{CIM}, the select signal SEL has the logic value “1”. In response to the select signal SEL having the logic value “1”, the selector 502 transmits the input data DIN to the memory array 104.

In some embodiments, when the accumulation size N_{CH} is smaller than the accumulation size N_{CIM}, the selector 502 receives the select signal SEL having the logic value “0”. In response to the select signal SEL having the logic value “0”, the selector 502 transmits the input data DIN to the buffer circuit 105.

In some embodiments, the write driver 501 is configured to provide a driving voltage that transmits the input data DIN. In some embodiments, the selector 502 is implemented by multiple logic gates.

In some embodiments, the write circuit 101 includes one or more logic circuit 500, and is configured to receive transmit multiple input data DIN.

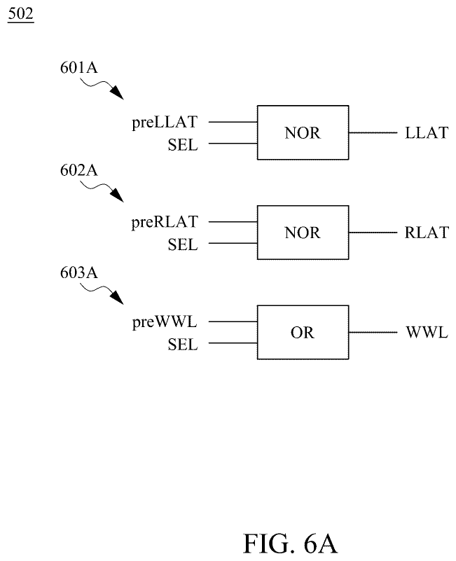

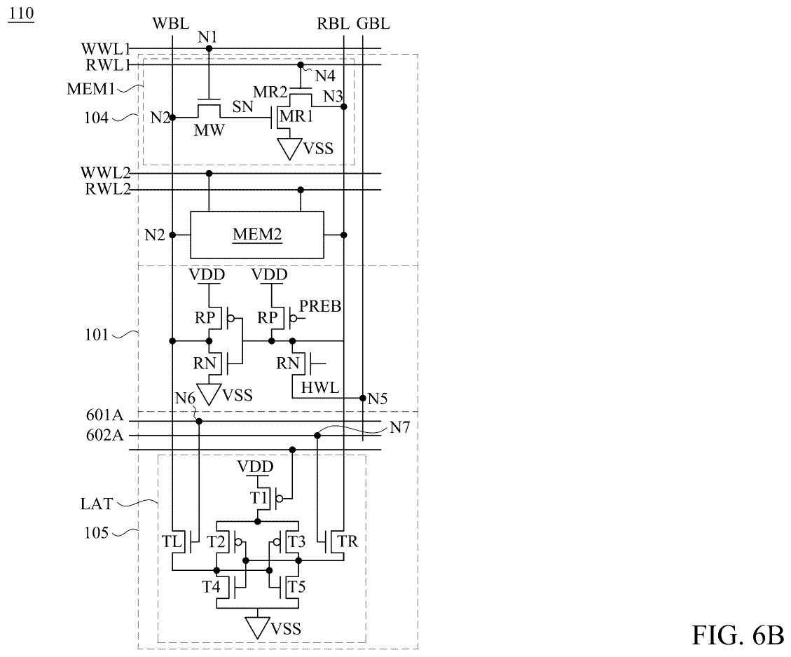

FIG. 6A is a schematic diagram of further details of the selector 502 shown in FIG. 5, illustrated in accordance with some embodiments of the present disclosure. As illustratively shown in FIG. 6A, the selector 502 includes logic gates 601A, 602A, and 603A.

In some embodiments, a first input terminal of the logic gate 601A is configured receive a voltage signal preLLAT. A second input terminal of the logic gate 601A is configured to receive the select signal SEL. An output terminal of the logic gate 601A is configured to generate a voltage signal LLAT. A first input terminal of the logic gate 602A is configured to receive a voltage signal preRLAT. A second input terminal of the logic gate 602A is configured to receive the select signal SEL. An output terminal of the logic gate 602A is configured to generate a voltage signal RLAT. A first input terminal of the logic gate 603A is configured to receive a write signal preWWL. A second input terminal of the logic gate 603A is configured to receive the select signal SEL. An output terminal of the logic gate 603A is configured to generate a write signal WWL.

In some embodiments of the present disclosure, each of the logic gates 601A and 602A has a first logic type. For example, each of the logic gates 601A and 602A is implemented by a NOR gate. The logic gate 603A has a second logic type. For example, the logic gate 603A is implemented by an OR gate.

In some embodiments, the voltage signal preLLAT has a voltage level VL. The voltage level VL corresponds to the logic value “0”. Accordingly, when the select signal SEL has the logic value “0”, the logic gate 601A outputs the voltage signal LLAT having the voltage level VH. The voltage level VH corresponds to the logic value “1”. In some embodiments, the voltage level VH is higher than the voltage level VL.

In some embodiments, the voltage signal preRLAT has a voltage level VL. Accordingly, when the select signal SEL has the logic value “0”, the logic gate 602A outputs the voltage signals RLAT having the voltage level VH.

In some embodiments, the voltage signal preWWL has a voltage level VL. Accordingly, when the select signal SEL has the logic value “1”, the logic gate 603A outputs the write signals WWL having the voltage level VH.

FIG. 6B is a circuit diagram of part of the processing circuit 110 as shown in FIG. 1, illustrated in accordance with some embodiments of the present disclosure. As illustratively shown in FIG. 6B, the circuit diagram includes the write circuit 101, the memory array 104, and the buffer circuit 105 of the processing circuit 110.

In some embodiments, the memory array 104 includes multiple memory cells, such as memory cells MEM1 and MEM2. The memory cells MEM1 includes switches MW, MR1 and MR2. The write circuit 101 includes switches RP, MP, RN, and NP. The buffer circuit 105 includes multiple latches, such as a latch LAT. The latch LAT includes multiple switches T1-T5, TL, and TR.

In some embodiments, a control terminal of the switch MW is configured to receive the voltage signal WWL at a node N1. A first terminal of the switch MW is coupled to a write bit line WBL at a node N2. A second terminal of the switch MW is coupled to a gate terminal of the switch MR1. A first terminal of the switch MR1 is coupled to a first terminal of the switch MR2. A second terminal of the switch MR1 is configured to receive a reference voltage signal VSS. A second terminal of the switch MR2 is coupled to a read bit line RBL at a node N3. A control terminal of the switch MR2 is coupled to a read word line RWL1 at a node N4. The memory cell MEM2 is coupled to each of a write word line WWL2, a read word line RWL2, the write bit line WBL and the read bit line RBL. The memory cell MEM2 is configured to receive the voltage signal WWL. In some embodiments, a configuration of the memory cell MEM2 is similar to the memory cell MEM1. Therefore, some descriptions are not repeated for brevity.

In some embodiments, a first terminal of the switch RP is coupled to the switch MW and the memory cell MEM2 at the node N2. A second terminal of the switch RP is configured to receive a voltage signal VDD. A control terminal of the switch RP is coupled to the read bit line RBL at the node N3. A first terminal of the switch RN is coupled to the switch MW and the memory cell MEM at the node N2. A second terminal of the switch RN is configured to receive the reference voltage signal VSS. A first terminal of the switch MP is coupled to the read bit line RBL at the node N3. A second terminal of the switch MP is configured to receive the voltage signal VDD. A control terminal of the switch MP is configured to receive a voltage signal PREB. A first terminal of the switch NP is coupled to the read bit line RBL at the node N3. A second terminal of the switch NP is coupled to a global bit line GBL at a node N5, and is configured to receive the input data DIN. A gate terminal of the switch NP is configured to receive a voltage signal HWL.

In some embodiments, a control terminal of the switch TL is coupled to the logic gate 601A at a node N6, and is configured to receive the voltage signal LLAT. A first terminal of the switch TL is coupled to the write bit line WBL and the memory array 104 at the node N2. A second terminal of the switch TL is coupled to each of a first terminal of the switch T2 and a first terminal of the switch T4 at a node N7. A control terminal of the switch TR is coupled to the logic gate 602A at a node N7, and is configured to receive the voltage signal RLAT. A first terminal of the switch TR is coupled to the read bit line RBL and the memory array 104 at the node N3. A second terminal of the switch TR is coupled to each of a first terminal of the switch N3 and a first terminal of the switch N5 at a node N8. A first terminal of the switch T1 is coupled to each of a second terminal of the switch T2 and a second terminal of the switch T3 at a node N9. Each of a control terminal of the switch T2 and a control terminal of the switch T4 is coupled to the switch TR at the node N8. Each of a control terminal of the switch T3 and a control terminal of the switch T5 is coupled to the switch TL at the node N7.

In some embodiments, a second terminal of the switch T1 is configured to receive the voltage signal VDD. A control terminal of the switch T1 is configured to receive a voltage signal PGATE. Each of a second terminal of the switch T4 and a second terminal of the switch T5 is configured to receive the reference voltage signal VSS.

In some embodiments, the reference voltage signal VSS has a ground voltage level. The reference voltage signal VDD has a power voltage level which is higher than the ground voltage level.

In some embodiments, each of the switches MW, MR1, MR2, RN, NP, T4, T5, TL, and TR is implemented by a transistor of a first conductive type, such as an N-type transistor. When a control terminal of the transistor of the first conductive type has the voltage level VH, the transistor is turned on. When a control terminal of the transistor of the first conductive type has the voltage level VL, the transistor is turned off.

In some embodiments, each of the switches RP, MP, and T1-T3 is implemented by a transistor of a second conductive type, such as a P-type transistor. When a control terminal of the transistor of the second conductive type has the voltage level VH, the transistor is turned off. When a control terminal of the transistor of the second conductive type has the voltage level VL, the transistor is turned on.

In some embodiments, the switch NP is turn on in response to the voltage signal HWL having the voltage level VH. Accordingly, the switch NP transmits the input data DIN to the write circuit 101. In some embodiments, the switch MP is turned on in response to the voltage signal PREB having the voltage level VL, such that the switch MP provides the voltage signal VDD to the write circuit 101.

In some embodiments, the switch T1 is turned on in response to the voltage signal PGATE having the voltage level VL, such that the switch T1 provides the voltage signal VDD to the buffer circuit 105.

Referring to FIG. 5, FIG. 6A and FIG. 6B, when the select signal SEL has the logic value “1”, the write word lines WWL1 and WWL2 transmit the write signal WWL having the voltage level VH to the switch MW and the memory cell MEM2, respectively.

At this moment, in response to the write signal WWL having the voltage level VH. the switch MW is turned on and generates a voltage signal SN to the control terminal of the switch MR1. The input data DIN is transmitted in order through each of the switches NP, RP, RP, and MW from the global bit line GBL to the switch MR1. Then, the input data DIN is stored to the switches MR1 and MR2 by the voltage signal SN. Similarly, the input data DIN is transmitted in order through each of the switches NP, RP, RP, and MW from the global bit line GBL to the memory cell MEM2, and the input data DIN is stored to the memory cell MEM2.

In some embodiments, the switch MW is configured to transmit one bit of the input data DIN, and the switches MR1 and MR2 are configured to store one bit of the input data DIN. Relatively, the memory cell MEM2 is configured to store multiple bits of the input data DIN.

Referring to FIG. 5, FIG. 6A and FIG. 6B, when the select signal SEL has the logic value “0”, the write word lines WWL1 and WWL2 transmit the write signal WWL having the voltage level VL to the switch MW and the memory cell MEM2, respectively. In response to the select signal SEL has the logic value “0”, each of the voltage signals LLAT and RLAT has the voltage level VH. The logic gate 601A transmits the voltage signal LLAT to the switch TL. The logic gate 602A transmits the voltage signal RLAT to the switch TL.

At this moment, in response to the voltage signals LLAT and RLAT having the voltage level VH, each of the switches TL and TR is turned on. When the switch TL is turned on, the input data DIN is transmitted in order through each of the switches NP, RP, RP, and TL from the global bit line GBL to the node N6. When the switch TR is turned on, the input data DIN is transmitted in order through each of the switches NP and TR from the global bit line GBL to the node N8. In some embodiments, each of the switches T2-T4 receives the input data DIN from the nodes N7 and N8 to store the input data DIN.

In some embodiments, the buffer circuit 105 includes one or more latches similar to the latch LAT. The latch LAT is implemented by a stationary latch in the present disclosure. The stationary latch stores one bit of the input data DIN. Accordingly, the quantity of bits of the weight filter W is determined by the quantity of latches in the buffer circuit 105. In some embodiments, the quantity of latches in the buffer circuit 105 is equal to the accumulation size NCIM. However, the present disclosure is not limited to the stationary latch storing one bit of the input data DIN. For example, a dual 4-bit latch can store four bits of data.

Referring to FIG. 5, FIG. 6A and FIG. 6B, in some embodiments, the selector 502 is implemented by the logic gates 601A-603A. The logic gate 601A is connected to the node N6, and transmits the voltage signal LLAT to the control terminal of the switch TL. The logic gate 602A is connected to the node N7, and transmits the voltage signal RLAT to the control terminal of the switch TR. The logic gate 603A is connected to the node N1, and transmits the write signal WWL to the control terminal of the switch MW.

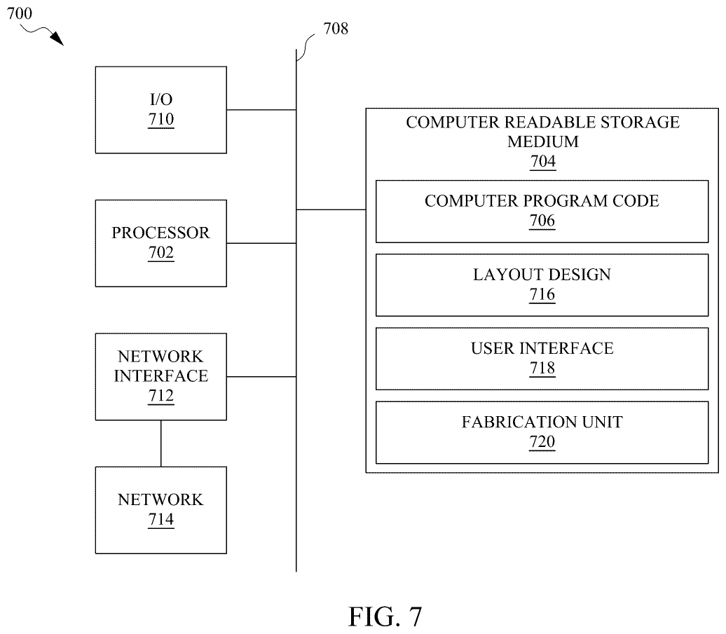

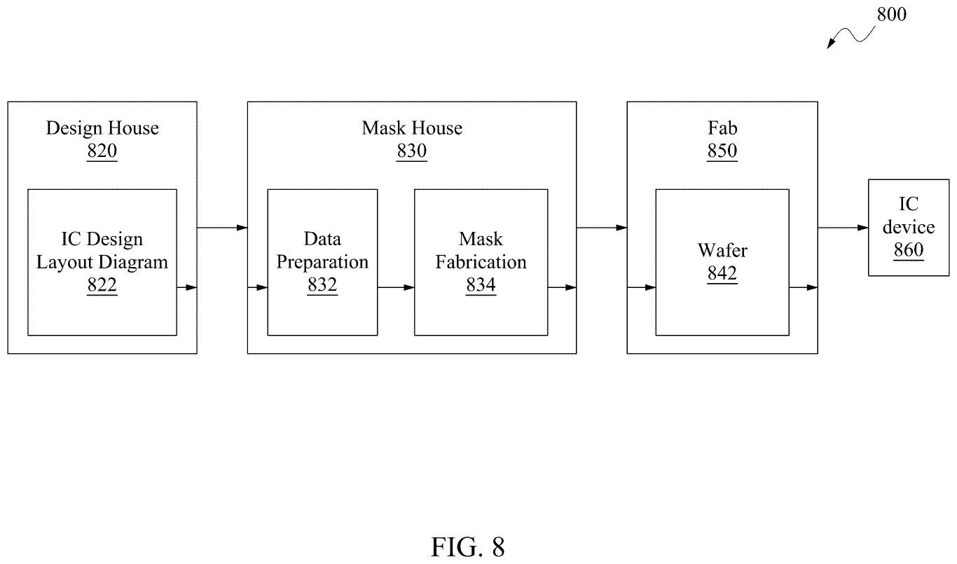

FIG. 7 is a schematic diagram of a system 700 for designing and manufacturing at least one of the semiconductor systems described herein, illustrated in accordance with some embodiments of the present disclosure. The system 700 generates or places one or more IC layout designs corresponding to at least one of the semiconductor systems described herein, as described herein. In some embodiments, the system 700 manufactures one or more semiconductor systems based on the one or more IC layout designs, as described herein. The system 700 includes a hardware processor 702 and a non-transitory, computer readable storage medium 704 encoded with, e.g., storing, the computer program code 706, e.g., a set of executable instructions. The computer readable storage medium 704 is configured for interfacing with manufacturing machines for producing the semiconductor device. The processor 702 is electrically coupled to the computer readable storage medium 704 by a bus 707. The processor 702 is also electrically coupled to an I/O interface 710 by the bus 707. A network interface 712 is also electrically connected to the processor 702 by the bus 707. Network interface 712 is connected to a network 714, so that the processor 702 and the computer readable storage medium 704 are capable of connecting to external elements via network 714. The processor 702 is configured to execute the computer program code 706 encoded in the computer readable storage medium 704 in order to cause the system 700 designing and manufacturing at least one of the semiconductor systems described herein.

In some embodiments, the processor 702 is a central processing unit (CPU), a multi-processor, a distributed processing system, an application specific integrated circuit (ASIC), and/or a suitable processing unit.

In some embodiments, the computer readable storage medium 704 is an electronic, magnetic, optical, electromagnetic, infrared, and/or a semiconductor system (or apparatus or device). For example, the computer readable storage medium 704 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 704 includes a compact disk-read only memory (CD-ROM), a compact disk-read/write (CD-R/W), and/or a digital video disc (DVD).

In some embodiments, the storage medium 704 also stores information needed for designing and manufacturing at least one of the semiconductor systems described herein, such as layout design 716, user interface 717, fabrication unit 720, and/or a set of executable instructions to designing and manufacturing at least one of the semiconductor systems described herein.

In some embodiments, the storage medium 704 stores instructions (e.g., the computer program code 706) for interfacing with manufacturing machines. The instructions (e.g., the computer program code 706) enable the processor 702 to generate manufacturing instructions readable by the manufacturing machines to effectively implement the semiconductor systems described herein.

The system 700 includes the I/O interface 710. The I/O interface 710 is coupled to external circuitry. In some embodiments, the I/O interface 710 includes a keyboard, keypad, mouse, trackball, trackpad, and/or cursor direction keys for communicating information and commands to the processor 702.

The system 700 also includes the network interface 712 coupled to the processor 702. The network interface 712 allows the system 700 to communicate with the network 714, to which one or more other computer systems are connected. The network interface 712 includes wireless network interfaces such as BLUETOOTH, WIFI, WIMAX, GPRS, or WCDMA; or wired network interface such as ETHERNET, USB, or IEEE-13154. In some embodiments, the designing and manufacturing of at least one of the semiconductor systems described herein is implemented in two or more systems 700, and information such as layout design, user interface and fabrication unit are exchanged between different systems 700 by the network 714.

The system 700 is configured to receive information related to a layout design through the I/O interface 710 or network interface 712. The information is transferred to the processor 702 by the bus 707 to determine a layout design for producing an IC. The layout design is then stored in the computer readable medium 704 as the layout design 716. The system 700 is configured to receive information related to a user interface through the I/O interface 710 or network interface 712. The information is stored in the computer readable medium 704 as the user interface 717. The system 700 is configured to receive information related to a fabrication unit through the I/O interface 710 or network interface 712. The information is stored in the computer readable medium 704 as the fabrication unit 720. In some embodiments, the fabrication unit 720 includes fabrication information utilized by the system 700.

In some embodiments, the designing and manufacturing of at least one of the semiconductor systems described herein is implemented as a standalone software application for execution by a processor. In some embodiments, the designing and manufacturing of at least one of the semiconductor systems described herein is implemented as a software application that is a part of an additional software application. In some embodiments, the designing and manufacturing of at least one of the semiconductor systems described herein is implemented as a plug-in to a software application. In some embodiments, the designing and manufacturing of at least one of the semiconductor systems described herein is implemented as a software application that is a portion of an EDA tool. In some embodiments, the designing and manufacturing of at least one of the semiconductor systems described herein is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated using a tool such as VIRTUOSO® available from CADENCE DESIGN SYSTEMS, Inc., or another suitable layout generating tool. In some embodiments, the layout design is generated based on a netlist which is created based on the schematic design. In some embodiments, at least one of the semiconductor systems described herein is implemented by a manufacturing device to manufacture an integrated circuit using a set of masks manufactured based on one or more layout designs generated by the system 700. In some embodiments, the system 700 includes a manufacturing device (e.g., fabrication tool 722) to manufacture an integrated circuit using a set of masks manufactured based on one or more layout designs of the present disclosure.

FIG. 8 is a block diagram of an integrated circuit (IC)/semiconductor device manufacturing system 800, and an IC manufacturing flow associated therewith, illustrated in accordance with some embodiments of the present disclosure.

In FIG. 8, the IC manufacturing system 800 includes entities, such as a design house 820, a mask house 830, and an IC manufacturer/fabricator (“fab”) 840, that interact with one another in the design, development, and manufacturing cycles and/or services related to manufacturing an IC device (semiconductor device) 860 including at least one of the semiconductor systems described herein. The entities in system 800 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 820, mask house 830, and IC fab 840 is owned by a single company. In some embodiments, two or more of design house 820, mask house 830, and IC fab 840 coexist in a common facility and use common resources.

The design house (or design team) 820 generates an IC design layout 822. The IC design layout 822 includes various geometrical patterns designed for the IC device 860. The geometrical patterns correspond to patterns of metal, oxide, or semiconductor layers that make up the various components of the IC device 860 to be fabricated. The various layers combine to form various IC features. For example, a portion of the IC design layout 822 includes various IC features, such as an active region, gate structures, source/drain structures, interconnect structures, and openings for bonding pads, to be formed in a semiconductor substrate (such as a silicon wafer) and various material layers disposed on the semiconductor substrate. The design house 820 implements a proper design procedure to form the IC design layout 822. The design procedure includes one or more of logic design, physical design or place and route. The IC design layout 822 is presented in one or more data files having information of the geometrical patterns. For example, the IC design layout 822 can be expressed in a GDSII file format or DFII file format.

The mask house 830 includes mask data preparation 832 and mask fabrication 834. The mask house 830 uses the IC design layout 822 to manufacture one or more masks to be used for fabricating the various layers of the IC device 860 according to the IC design layout 822. The mask house 830 performs the mask data preparation 832, where the IC design layout 822 is translated into a representative data file (“RDF”). The mask data preparation 832 provides the RDF to the mask fabrication 834. The mask fabrication 834 includes a mask writer. A mask writer converts the RDF to an image on a substrate, such as a mask (reticle) or a semiconductor wafer, or a metal layer which is formed and thereafter selectively etched to form a redistribution layer at a back end of line process of the fab. The design layout is manipulated by the mask data preparation 832 to comply with particular characteristics of the mask writer and/or requirements of the IC fab 840. In FIG. 8, the mask data preparation 832 and mask fabrication 834 are illustrated as separate elements. In some embodiments, the mask data preparation 832 and mask fabrication 834 can be collectively referred to as mask data preparation.

In some embodiments, the mask data preparation 832 includes optical proximity correction (OPC) which uses lithography enhancement techniques to compensate for image errors, such as those that can arise from diffraction, interference, other process effects and the like. OPC adjusts the IC design layout 822. In some embodiments, the mask data preparation 832 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 832 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 834, which may undo part of the modifications performed by OPC in order to meet mask creation rules.

In some embodiments, the mask data preparation 832 includes lithography process checking (LPC) that simulates processing that will be implemented by the IC fab 840 to fabricate the IC device 860. LPC simulates this processing based on the IC design layout 822 to create a simulated manufactured device, such as the IC device 860. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 822.

It should be understood that the herein description of the mask data preparation 832 has been simplified for the purposes of clarity. In some embodiments, the mask data preparation 832 includes additional features such as a logic operation (LOP) to modify the IC design layout according to manufacturing rules. Additionally, the processes applied to the IC design layout 822 during the mask data preparation 832 may be executed in a variety of different orders.

After the mask data preparation 832 and during mask fabrication 834, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 834 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 840 is an IC fabrication entity that includes one or more manufacturing facilities for the fabrication of a variety of different IC products. In some embodiments, the IC fab 840 is a semiconductor foundry. For example, there may be a first manufacturing facility for the front end fabrication of a plurality of IC products (e.g., source/drain structures, gate structures), while a second manufacturing facility may provide the middle end fabrication for the interconnection of the IC products (e.g., MDs, VDs, VGs) and a third manufacturing facility may provide the back end fabrication for the interconnection and packaging of the IC products (e.g., M0 tracks, M1 tracks, BM0 tracks, BM1 tracks), and a fourth manufacturing facility may provide other services for the foundry entity.

The IC fab 840 uses the mask (or masks) fabricated by the mask house 830 to fabricate the IC device 860. Thus, the IC fab 840 at least indirectly uses the IC design layout 822 to fabricate the IC device 860. In some embodiments, a semiconductor wafer is fabricated by the IC fab 840 using the mask (or masks) to form the IC device 860. The semiconductor wafer 842 includes a silicon substrate or other proper substrate having material layers formed thereon. Semiconductor wafer further includes one or more of various doped regions, dielectric features, multilevel interconnects, and the like (formed at subsequent manufacturing steps).

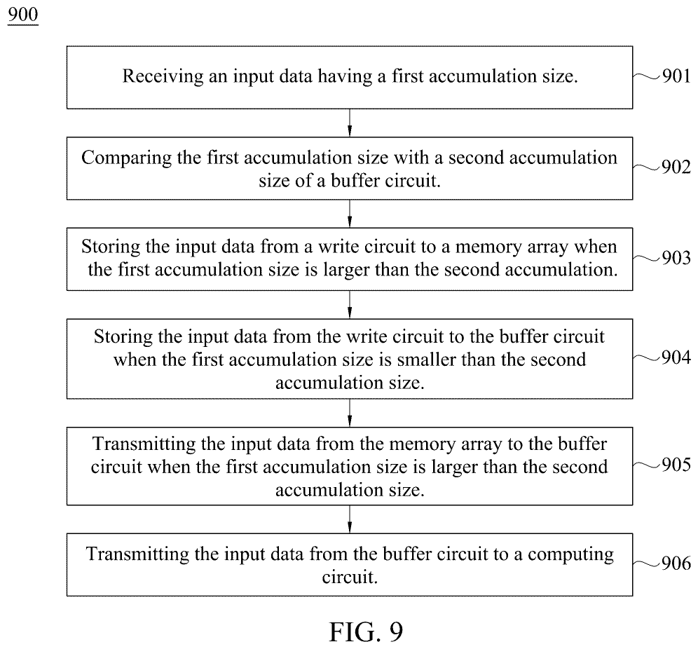

FIG. 9 is a flow diagram of a method 900 of operating the semiconductor system 100, illustrated in accordance with some embodiments of the disclosure. As shown in FIG. 9, the method 900 includes operations 901-905.

At the operation 901, receive an input data having a first accumulation size.

For example, the write circuit 101 receives the input data DIN having the accumulation size NCH from the buffer circuit 120. The semiconductor system 100 performs the operation 902 after the operation 901 is performed.

At the operation 902, compare the first accumulation size with a second accumulation size of a first buffer circuit.

For example, the select circuit 102 compares the accumulation size NCH with the accumulation size NCIM. The semiconductor system 100 performs the operation 903 after the operation 902 is performed.

At the operation 903, store the input data from a write circuit to a memory array when the first accumulation size is larger than the second accumulation size.

For example, the write circuit 101 stores the input data DIN to the memory array 104 when the accumulation size NCH is larger than the accumulation size NCIM. The semiconductor system 100 performs the operation 904 after the operation 903 is performed.

At operation 904, store the input data from the write circuit to the buffer circuit when the first accumulation size is smaller than the second accumulation size.

For example, the write circuit 101 stores the input data DIN to the buffer circuit 105 when the accumulation size NCH is smaller than the accumulation size NCIM. The semiconductor system 100 performs the operation 905 after the operation 904 is performed.

At operation 905, transmit the input data from the memory array to the buffer circuit when the first accumulation size is larger than the second accumulation size.

For example, the memory array 104 further transmits the input data DIN to the buffer circuit 105 when the accumulation size NCH is larger than the accumulation size NCIM. The semiconductor system 100 performs the operation 906 after the operation 905 is performed.

At operation 906, transmit the input data from the buffer circuit to a computing circuit.

For example, the input data DIN is transmitted from the buffer circuit 105 to the computing circuit 106. In some embodiments, the input data DIN is transmitted to the computing circuit 106 configured to perform a computation process, such as the CNN process 300 as shown in FIG. 3. The method 900 is completed after the operation 906 is performed.

In some embodiments, the method 900 also comprises generating a select signal according to each of the first accumulation size and the second accumulation size, wherein the select signal has a first logic value when the first accumulation size is smaller than the second accumulation size, and the select signal has a second logic value when the first accumulation size is larger than the second accumulation size.

For example, the select circuit 102 generates the select signal SEL according to each of the accumulation size NCH and the accumulation size NCIM. The select signal SEL has the logic value “0” when the accumulation size NCH is smaller than the accumulation size NCIM. The select signal SEL has the logic value “1” when the accumulation size NCH is larger than the accumulation size NCIM.

In some embodiments, when the select signal has the first logic value, turning on a first switch in the buffer circuit and a second switch in the buffer circuit, and storing the input data into the buffer circuit when each of the first switch and the second switch is turned on.

For example, when the select signal SEL has the logic value “0”, the logic gate 601A turns on the switch TL, and the logic gate 602A turns on the switch TR, such that the input data DIN is stored in the buffer circuit.

In some embodiments, when the select signal has the second logic value, turning on a third switch in the memory array, and storing the input data into the memory array when the third switch is turned on.

For example, when the select signal SEL has the logic value “1”, the logic gate 603A turns on the switch MW, such that the input data DIN is stored in the memory array 104.

Also disclosed is a semiconductor system. The semiconductor system comprises a write circuit configured to receive an input data having a first accumulation size; a first buffer circuit having a second accumulation size, and configured to store the input data when the first accumulation size is smaller than the second accumulation size; and a memory array configured to store the input data and transmit the input data to the first buffer circuit when the first accumulation size is larger than the second accumulation size of the input data.

Also disclosed is a semiconductor system. The semiconductor system comprises a selector circuit configured to generate a select signal according to an input data having a first accumulation size; and a buffer circuit having a second accumulation size, and configured to store the input data when the select signal has a first logic value; and a memory array configured to store the input data when the select signal has a second logic value and transmit the input data to the buffer circuit; wherein when the first accumulation size is smaller than the second accumulation size, the select signal has the first logic value, and when the first accumulation size is larger than the second accumulation size, the select signal has the second logic value.

Also disclosed is a method. The method comprises receiving an input data having a first accumulation size; comparing the first accumulation size with a second accumulation size of a buffer circuit; storing the input data from a write circuit to a memory array when the first accumulation size is larger than the second accumulation size; storing the input data from the write circuit to the buffer circuit when the first accumulation size is smaller than the second accumulation size; transmitting the input data from the memory array to the buffer circuit when the first accumulation size is larger than the second accumulation size; and transmitting the input data from the buffer circuit to a computing circuit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor system, comprising:
a write circuit configured to receive an input data having a first accumulation size;
a first buffer circuit having a second accumulation size, and configured to store the input data when the first accumulation size is smaller than the second accumulation size; and
a memory array configured to store the input data and transmit the input data to the first buffer circuit when the first accumulation size is larger than the second accumulation size of the input data.

2. The semiconductor system of claim 1, further comprising:
a selector circuit configured to generate a select signal according to the input data, to control the write circuit,
wherein when the first accumulation size is larger than the second accumulation size, the select signal has a first logic value,
when the first accumulation size is smaller than the second accumulation size, the select signal has a second logic value, and
the first logic value is different from the second logic value.

3. The semiconductor system of claim 2, wherein
when the select signal has the first logic value, the write circuit transmits the input data to the memory array, and the memory array stores the input data, and
when the select signal has the second logic value, the write circuit transmits the input data to the first buffer circuit, and the first buffer stores the input data.

4. The semiconductor system of claim 2, further comprising:
a first switch configured to transmit the input data to the memory array, wherein the first switch is turned on when the select signal has the first logic value.

5. The semiconductor system of claim 4, further comprising:
a second switch configured to transmit the input data to the buffer circuit; and
a third switch configured to transmit the input data to the buffer circuit,
wherein each of the second switch and the third switch is turned on when the select signal has the second logic value.

6. The semiconductor system of claim 5, wherein the write circuit further comprises:
a logic circuit configured to receive the select signal and generate a first voltage signal, a second voltage signal, and a write signal according to the select signal,
a control terminal of the first switch is configured to receive the write signal,
a control terminal of the second switch is configured to receive the first voltage signal, and
a control terminal of the third switch is configured to receive the second voltage signal.

7. The semiconductor system of claim 6, wherein
when the select signal has the first logic value, the write signal has a first voltage level, and each of the first voltage signal and the second voltage signal has a second voltage level, and
the first voltage level is different from the second voltage level.

8. The semiconductor system of claim 6, wherein
when the select signal has the second logic value, the first voltage signal has a second voltage level, and the second voltage signal has the second voltage level,
the first switch is turned when the write signal has the first voltage level, and
the second switch and the third switch are turned on when the first voltage signal and the second signal have the first voltage level, respectively.

9. The semiconductor system of claim 6, wherein the selector circuit comprises:
a first logic gate configured to generate the first voltage signal;
a second logic gate configured to generate the second voltage signal; and
a third logic gate configured to generate the write signal,
wherein each of the first logic gate and the second logic gate has a first logic type, and the third logic gate has a second logic type different from the first logic type.

10. A semiconductor system, comprising:
a selector circuit configured to generate a select signal according to an input data having a first accumulation size;
a buffer circuit having a second accumulation size, and configured to store the input data when the select signal has a first logic value; and
a memory array configured to store the input data when the select signal has a second logic value and transmit the input data to the buffer circuit;
wherein when the first accumulation size is smaller than the second accumulation size, the select signal has the first logic value, and
when the first accumulation size is larger than the second accumulation size, the select signal has the second logic value.

11. The semiconductor system of claim 10, further comprising:
a write circuit coupled to each of the memory array and the buffer circuit, and configured to transmit the input data to the memory array and the buffer circuit according to the select signal, the write circuit comprising:
a selector configured to generate a write signal according to the select signal,
wherein when the select signal has the first logic value, the write signal has a first voltage level, and
when the select signal has the second logic value, the write signal has a second voltage level different from the first voltage level.

12. The semiconductor system of claim 11, further comprising:
a first switch, the first switch is turned on in response to the write signal having the second voltage level, and turned off in response to the write signal having the first voltage level.

13. The semiconductor system of claim 11, wherein the selector is further configured to generate a first voltage signal and a second voltage signal according to the select signal,
when the select signal has the first logic value, each of the first voltage signal and the second voltage signal has the second voltage level, and
when the select signal has the second logic value, each of the first voltage signal and the second voltage signal has the first voltage level.

14. The semiconductor system of claim 13, further comprising:
a second switch configured be turned on in response to the first voltage signal having the second voltage level; and
a third switch configured to be turned on in response to the second voltage signal having the second voltage level.

15. The semiconductor system of claim 11, wherein the selector comprises:
a first logic gate configured to generate the first voltage signal; and
a second logic gate configured to generate the write signal,
wherein the first logic gate has a first logic type, and the second logic gate has a second logic type different from the first logic type.

16. The semiconductor system of claim 1, wherein
when the first accumulation size is larger than the second accumulation size, the write circuit transmits the input data to the memory array, and the memory array transmits a first part of the input data to the buffer circuit, and
a quantity of bits in the first part is equal to the second accumulation size, and the quantity of bits in the first part is smaller than the first accumulation size.

17. A method, comprising:
receiving an input data having a first accumulation size;
comparing the first accumulation size with a second accumulation size of a buffer circuit;
storing the input data from a write circuit to a memory array when the first accumulation size is larger than the second accumulation size;
storing the input data from the write circuit to the buffer circuit when the first accumulation size is smaller than the second accumulation size;
transmitting the input data from the memory array to the buffer circuit when the first accumulation size is larger than the second accumulation size; and
transmitting the input data from the buffer circuit to a computing circuit.

18. The method of claim 17, further comprising:
generating a select signal according to each of the first accumulation size and the second accumulation size,
wherein the select signal has a first logic value when the first accumulation size is smaller than the second accumulation size, and
the select signal has a second logic value when the first accumulation size is larger than the second accumulation size.

19. The method of claim 18, further comprising:
when the select signal has the first logic value, turning on a first switch in the buffer circuit and a second switch in the buffer circuit, and
storing the input data into the buffer circuit when each of the first switch and the second switch is turned on.

20. The method of claim 18, further comprising:
when the select signal has the second logic value, turning on a third switch in the memory array, and
storing the input data into the memory array when the third switch is turned on.
